(19) United States
(12) Patent Application Publication
(10) Pub. No.: US 2021/0255377 A1
(43) Pub. Date: Aug. 19, 2021

(54) 3D IDENTIFICATION FILTER

(71) Applicant: FUZHO PHOTOP OPTICS CO., LTD, Fuzhou, Fujian (CN)

(72) Inventors: Zhe LIU, Fujian (CN); Guanglong YU, Fujian (CN); Yu LI, Fujian (CN); Yan SU, Fujian (CN); Li WU, Fujian (CN); Zhiqiang LIN, Fujian (CN)

(21) Appl. No.: 17/259,419

(22) PCT Filed: Sep. 12, 2018
(86) PCT No.: PCT/CN2018/105142

§ 371 Date: Jan. 11, 2021

(30) Foreign Application Priority Data
Jul. 18, 2018 (CN) 201810790443.3

(51) Int. Cl. G02B 5/28; C23C 14/35; C23C 14/46; C23C 14/08; C23C 14/06

(52) U.S. Cl. CPC G02B 5/285; G02B 5/281; C23C 14/0652; C23C 14/46; C23C 14/08; C23C 14/352

(57) ABSTRACT

A 3D identification filter (101) is provided, which has a passband partially overlapping with a wavelength range of 800 nm to 1800 nm and a blocking band containing a range of 380 nm to 750 nm, and comprises a substrate (102) and filter film layers (103, 104) coated on both surfaces of the substrate, wherein the filter film layer (103) on one of the surfaces is composed of high refractive index layers, medium refractive index layers, and low refractive index layers that are stacked, and the filter film layer (104) on the other surface is composed of at least two layers of materials that are stacked. The 3D identification filter (101) maintains a high bocking level and a narrow transition band while achieving a small wavelength shift at a large light incident angle.

### TECHNICAL FIELD

The present invention relates to the field of filters, and in particular, to a 3D identification filter.

### BACKGROUND

Three-dimensional (3D) identification technology has been widely used in machine vision, virtual reality, identity recognition, autonomous driving, and other fields. Compared with two-dimensional imaging, 3D identification can obtain stereoscopic information of an object being detected. The basic principle of 3D identification is to emit infrared light of a certain waveband, and use a sensor to receive light of that waveband returned by the object being detected, to obtain distance information through signal processing, thereby establishing a three-dimensional model of the object being detected. A typical 3D identification module includes an infrared light source, a modulation device, and lenses at the transmitting end, and includes an infrared detector, lenses, an infrared filter, etc. at the receiving end.

For 3D identification, the infrared filter at the receiving end is quite different from a filter in a conventional visible light camera. The filter in the conventional visible light camera is often of infrared cutoff type, while the 3D identification filter: (a) only allows light of a specific waveband (corresponding to the infrared light source at the transmitting end) to pass through, and needs to highly block light of other wavebands, especially visible light, to achieve the purpose of filtering noise and improving the signal-to-noise ratio of the system, and (b) 3D identification needs to detect stereoscopic information within a certain angle, so the filter needs to accommodate enough light incident angle (such as 20 to 40 degrees). Since the passband bandwidth and the blocking band depth determine the ability of the filter to filter noise, it is desirable that the 3D identification filter has a passband position that is as insensitive as possible to the light incident angle, and at the same time has a high blocking level for light of other wavebands, especially visible light.

The filter used in the 3D identification module is mainly based on the principle of interference. Tens to hundreds of films are deposited on a transparent substrate (such as glass) through a vacuum coating technology. Generally, there are at least two film materials, and the main factors that affect the final performance of the filter are the refractive index and the deposition thickness of each layer of material. According to the optical interference multilayer film theory, if the center wavelength of the bandpass film system at the incident angle of 0 is λ₀, the center wavelength λ_{Θ} of the film system at the incident angle of Θ has the following relationship with λ₀:

$$\frac{{λ}_{θ}}{{λ}_{0}} = \frac{\sqrt{{n}^{2} - {sin}^{2} θ}}{n}$$

Where n is the equivalent refractive index of the film system, which is determined by the order of the cavity layer in the film system and the refractive index of the material. Assuming a second-order cavity is used, the equivalent refractive index of the film system is (see H. Angus Macloed, Thin-Film Optical Filters, fourth edition, Chapter 8):

$$n = {n}_{H} \sqrt{\frac{2 - \frac{{n}_{L}}{{n}_{H}}}{1 - \frac{{n}_{L}}{{n}_{H}} + \frac{{n}_{H}}{{n}_{L}}}}$$

The film system is composed of two layers of materials of high and low refractive indexes, where n_{H} is the refractive index of the high refractive index layer, and n_{L} is the refractive index of the low refractive index layer. Based on these two formulas, the refractive index of the material required to achieve low angle drift can be easily estimated. For example, if a filter with a center wavelength of 850 nm at an incident angle of 0 degree is desired to have a center wavelength of not less than 830 nm at an incident angle of 30 degrees, the equivalent refractive index n of the film system is required to be not less than 2.3; assuming the low refractive index layer is SiO₂ with a refractive index of 1.48, low angle drift can be achieved as long as the refractive index of the high refractive index layer is not less than 3.1. One conventional method for preparing materials with a refractive index greater than 3 is to use Si:H materials. In 2004, Hidenhiko Yoda et al. disclosed a method entitled “a-Si: H/SiO₂ multilayer films fabricated by radio-frequency magnetron sputtering for optical filters” (The Optical Society of American, Applied Optics, 2004, Vol. 43, No. 17), which can prepare Si:H with a refractive index greater than 3.5 at a waveband range of 800 to 1800 nm, and the Si:H material is transparent at the waveband range of 800 to 1800 nm.

However, there are still some problems with an existing 3D filter based on the method of a multi-cavity bandpass film system with high and low refractive indexes as described above: (a) the Si:H material has strong absorption of light with the wavelength of below 600 nm, but has not complete absorption of light in the wavelength range of 600 to 800 nm, resulting in the difficulty for the filter to have a high blocking level for this range; (b) to further reduce the angle drift, the order of the cavity layer needs to be increased, and in order to maintain the bandwidth of the passband, increasing the order of the cavity layer inevitably increases the mismatch between various optical cavities, resulting in the deterioration of the jitter of the filter and the widening of the transition band; and (c) due to the influence of (b), in order to maintain the jitter of the filter, the number of cavities needs to be increased significantly, resulting in a significant increase in the number of filter film layers and an increase in preparation difficulty.

### SUMMARY

The objective of the present invention is to provide a 3D identification filter, which is a technical improvement to the existing 3D identification filter. It maintains a high bocking level and a narrow transition band while achieving a small wavelength shift at a large light incident angle.

In order to achieve the above objective, the present invention adopts the following technical solution:

a 3D identification filter having a passband partially overlapping with a wavelength range of 800 nm to 1800 nm and a blocking band containing a range of 380 nm to 750 nm, which comprises a substrate and filter film layers coated on both surfaces of the substrate.

The filter film layer on one of the surfaces is composed of high refractive index layers, medium refractive index layers, and low refractive index layers that are stacked; the high refractive index layers are Si:H, and the refractive index of each high refractive index layer at 800 to 1800 nm is greater than 3; the refractive index of each medium refractive index layer at 800 to 1800 nm is greater than 1.6 and less than 3; the refractive index of each low refractive index layer at 800 nm to 1800 nm is less than 1.6; and the ratio of total physical thicknesses of all high refractive index layers and all low refractive index layers is greater than 1.5:1.

The filter film layer on the other surface is composed of at least two layers of materials that are stacked, and the number of layers is not less than 15.

The passband of the filter has a center wavelength that shifts less than 20 nm when the angle of incident light changes from 0 degree to 30 degrees; the blocking level of the blocking band of the filter for a range of 380 nm to 750 nm is greater than OD4; and the edge of the passband of the filter is provided with a transition band, and the width of the transition band from 90% transmittance to 10% transmittance is less than 5 nm.

The material of the substrate is a silicon material, or a glass material based on silica, or plastic, or sapphire. The passband has a center wavelength, and when the angle of incident light changes from 0 degree to 30 degrees, the shift of the center wavelength is less than 12 nm.

The medium refractive index layer is one of Si:H, TiO₂, Nb₂O₅, Ta₂O₅, SiO₂, and SiₓN_{y}, or a mixture of at least two of them; and when it is a mixture, the refractive index thereof has a property of being continuously adjustable in a range from 1.6 to 3 through process proportioning; or the medium refractive index layer is SiOₓ:H, and the refractive index thereof has a property of being continuously adjustable in the range from 1.6 to 3 through process adjustment of the stoichiometric ratio of element components;

or the medium refractive index layer is SiNₓ:H, and the refractive index thereof has a property of being continuously adjustable in the range from 1.6 to 3 through process adjustment of the stoichiometric ratio of element components.

The low refractive index layer is SiO₂.

The present invention adopts the above technical solution to maintain a high blocking level and a narrow transition band while achieving a small wavelength shift at a large light incident angle.

The present invention further discloses a manufacturing method for implementing the 3D identification filter. The method adopts a mode of mid-frequency magnetron sputtering or ion beam sputtering to form a Si:H film layer by introducing hydrogen into a chamber of a sputtering machine. The present invention discloses various methods for adjusting optical properties of a deposited film layer required to realize the technical solution: the flow rate of hydrogen can be regulated to adjust the optical properties of the Si:H film layer; the flow rates of hydrogen and oxygen can be simultaneously regulated to adjust the stoichiometric ratio of element components of a SiOₓ:H film layer, and then adjust the refractive index of SiOₓ:H; the flow rates of nitrogen and hydrogen can be simultaneously regulated to adjust the stoichiometric ratio of element components of a SiNₓ:H film layer, and then adjust the refractive index of SiNₓ:H; and at least two materials can be co-deposited, and the refractive index of the mixture film layer is adjusted by adjusting the ratio of the materials.

### DESCRIPTION OF THE DRAWINGS

The present invention will be further described in detail below in conjunction with the drawings and specific implementations:

FIG. 1 is a schematic diagram of the present invention.

FIG. 2 is a diagram of transmission spectra of an exemplary conventional 3D identification filter at an incident angle of 0 degree and 30 degrees, wherein the horizontal axis is wavelength (nm) and the vertical axis is transmittance (%).

FIG. 3 is a diagram of optical density of the exemplary conventional 3D identification filter at 0 degree, wherein the horizontal axis is wavelength (nm) and the vertical axis is optical density (dimensionless).

FIG. 4 is a diagram of transmission spectra of a 3D identification filter according to an embodiment of the present invention at an incident angle of 0 degree and 30 degrees, wherein the horizontal axis is wavelength (nm) and the vertical axis is transmittance (%).

FIG. 5 is a diagram of optical density of the 3D identification filter according to the embodiment of the present invention at 0 degree, wherein the horizontal axis is wavelength (nm) and the vertical axis is optical density (dimensionless).

FIG. 6 is a schematic diagram of an ion beam sputtering system.

FIG. 6b is a schematic timing diagram of the voltage at the target of the mid-frequency magnetron sputtering system of FIG. 6a, wherein the horizontal axis is time and the vertical axis is voltage.

FIG. 7 is a schematic diagram of the relationship between the flow rate of hydrogen and the refractive index n and the extinction coefficient k of the deposited Si:H film layer.

FIG. 8 is a schematic diagram of the relationship between the ratio of the flow rates of hydrogen and oxygen and the refractive index of the deposited SiOₓ:H film layer.

FIG. 9 is a schematic diagram of the relationship between the ratio of the flow rates of hydrogen and nitrogen and the refractive index of the deposited SiNₓ:H film layer.

FIG. 10 is an apparatus that supports co-sputtering of two materials to make the refractive index of the deposited film layer continuously controllable.

FIG. 11 is another apparatus that supports co-sputtering of two materials to make the refractive index of the deposited film layer continuously controllable.

### DETAILED DESCRIPTION

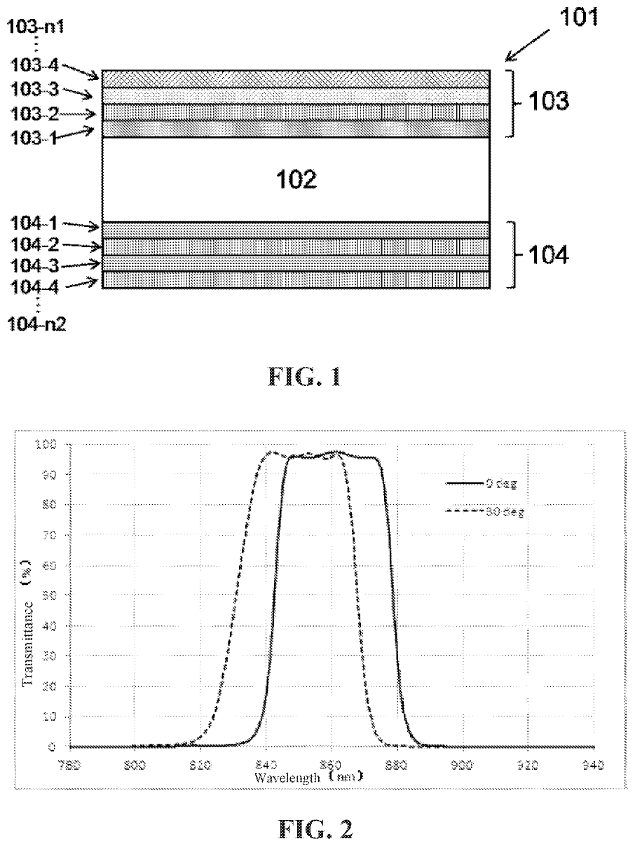

As shown in FIG. 1, a 3D identification filter 101 of the present invention comprises a substrate 102, a filter film layer 103 deposited on one surface of the substrate 102, and a filter film layer 104 deposited on the other surface of the substrate 102. The substrate 102 transmits light of the working waveband of the filter, and plays a role of supporting the filter. In general, when the passband of the filter is in the range of 800 to 1000 nm, the substrate material is preferably an optical glass having good light transmittance, such as BK7, D263T, and B270. When the filter passband is near the 1550 nm waveband, the substrate 102 can be selected as a silicon substrate. In particular, colored glass having an absorption effect on a specific waveband can also be used to further increase the blocking level; and by tempering the glass, the mechanical strength of the substrate can be further improved.

Filter film layer 103 coated on one surface of the substrate (hereinafter simply referred to as “a bandpass film surface”) is composed of high refractive index layers, medium refractive index layers, and low refractive index layers that are stacked. The high refractive index layers are Si:H, of which the refractive index at 800 to 1800 nm is greater than 3; the refractive index of each medium refractive index layer at 800 to 1800 nm is greater than 1.6 and less than 3; and the refractive index of each low refractive index layer at 800 nm to 1800 nm is less than 1.6. The ratio of physical thicknesses of all high refractive index layers and all low refractive index layers is greater than 1.5:1. Taking FIG. 1 as an example, the layer 103-1 may be a high refractive index layer Si:H, the layer 103-2 may be a medium-low refractive index layer denoted as M1, the layer 103-3 may be a low refractive index layer such as SiO₂, and the layer 103-4 may be another medium refractive index layer denoted as M2. Each layer of material is alternately stacked, and the total number of film layers is n1. The filter film layer 104 coated on the other surface of the substrate (hereinafter simply referred to as “a blocking film surface”) is composed of at least two layers of materials that are stacked. Each layer of material is alternately stacked, the total number of film layers is n2, and n2>15. The number of film layers and the order of material stacking in FIG. 1 are for illustrative purposes only. The actual number of film layers and the stacking order in actual use can be designed according to the application requirements of the filter.

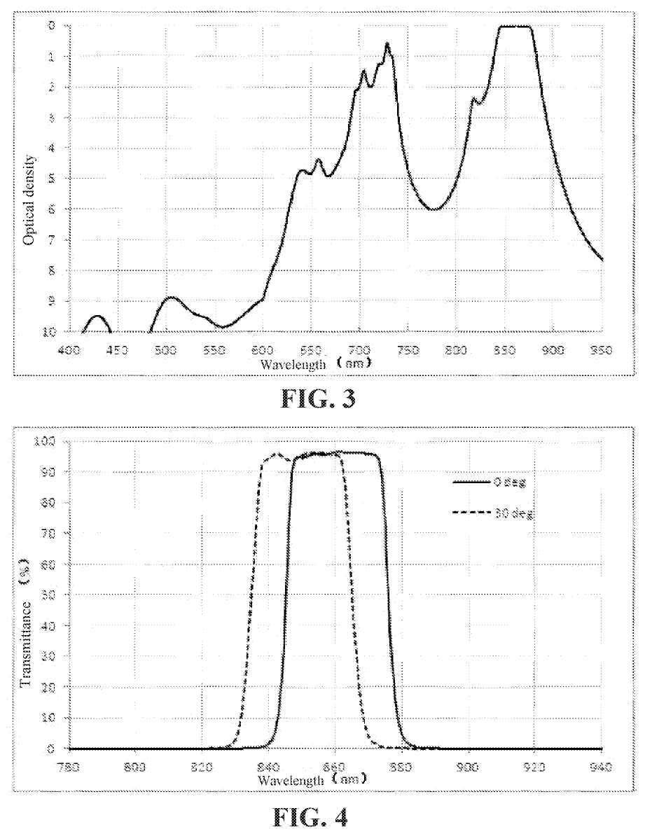

FIG. 2 and FIG. 3 depict the spectral performance of a prior art 3D identification filter, which is designed to transmit light from 848 nm to 861 nm over an incident angle of 0 to 30 degrees. The bandpass film surface is composed of a high refractive index layer and a low refractive index layer that are alternately stacked. The high refractive index layer uses Si:H. and the refractive index near 860 nm is 3.62; and the low refractive index layer uses SiO₂, and the refractive index near 860 nm is 1.48. The total number of film layers on filter film surfaces is 41, and the total physical thickness is 4.4 μm. On the other surface of the substrate, an anti-reflection (AR) film is coated to improve the passband transmittance near 860 nm. The AR film is composed of Ta₂O₅ and SiO₂ materials that are alternately stacked, and the number of layers is 5. Since the AR film only serves to reduce the reflection of the back surface, both the jitter of the transition band and the blocking band depth of the filter are determined by the bandpass film surface.

FIG. 2 is a diagram of transmission spectra of the exemplary 3D identification filter at an incident angle of 0 degree and 30 degrees, wherein the vertical axis is transmittance. As described above, based on the optical film theory, when the cavity layer is made of a material having a refractive index greater than 3, and the equivalent refractive index can satisfy the obvious relationship, a low angular shift can be achieved. In this design, the initial order of cavity layer is 2, the number of cavity layers is 7, and a shift of the passband center wavelength (defined as a center position of two wavelength points at 90% transmittance) at an incident angle of 30 degrees is less than 10 nm.

It is worth mentioning that the shift of this filter has been close to the best level of the existing 3D identification filter technology. However, in order to reduce the angular shift, high-order cavities are used to increase the mismatch between optical cavities to obtain the bandwidth required by an application, which leads to the sacrifice of the jitter of the transition band between the passband and the blocking band: the width of the transition band at wavelength points from 90% transmittance to 10% transmittance achieved by a 41-layer, 7-cavity film system is 6.8 nm in the short-waveband direction and 6.9 nm in the long-waveband direction. To continue to increase the jitter, the number of cavities, that is the number of layers of the film system, needs to be increased, and the corresponding preparation difficulty will also increase significantly.

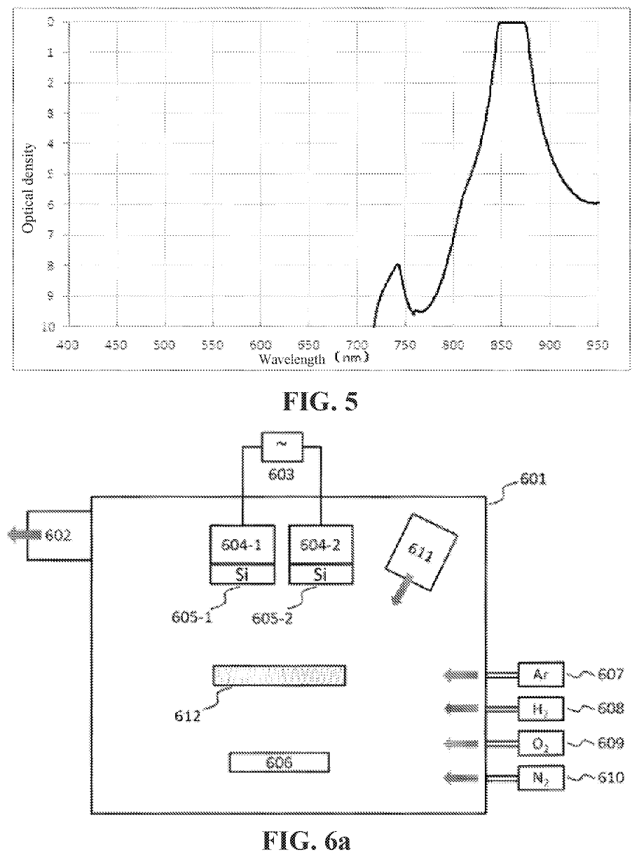

FIG. 5 is a diagram of optical density of the exemplary conventional 3D identification filter at 0 degree. The conversion relationship between the optical density OD and the transmittance T (unit: %) is: OD=−log₁₀(T/100), and the optical density visually indicates the blocking level of the filter. Benefiting from the absorption of short-waveband light by Si:H, the filter can reach a high blocking level below 600 nm. However, near the range of 700 nm to 730 nm, due to the incomplete absorption by Si:H, the OD4 blocking range of the filter cannot cover the entire visible light waveband.

FIG. 4 and FIG. 5 depict the spectral performance of a 3D identification filter according to an embodiment of the present invention. Similarly, the 3D identification filter is also designed to transmit light from 848 nm to 861 nm at an incident angle of 0 to 30 degrees, which is equivalent to the 3D filter of FIG. 2 and FIG. 3. The filter film layer on the bandpass film surface of this embodiment is composed of a high refractive index layer, a medium refractive index layer and a low refractive index layer that are stacked, wherein the high refractive index layer is Si:H, and the refractive index near 860 nm is 3.62; the low refractive index layer uses SiO₂ and has a refractive index of 1.48 near 860 nm; and two medium refractive index layers are used, wherein the first medium refractive index layer M1 has a refractive index of 1.91 near 860 nm, and the second medium refractive index layer M2 has a refractive index of 2.71 near 860 nm. The number of film layers on the bandpass film surface is 19, and the total thickness is 4.1 μm. The film layer on the blocking film surface of this embodiment is composed of two layers of materials of Si:H and SiO₂, and the number of layers is 31. The jitter of the transition band of the filter of the present embodiment is determined by the film system of the bandpass film surface, and the depth of the blocking band is determined by the film system on both the bandpass film surface and the blocking film surface.

FIG. 4 is a diagram of transmission spectra of a 3D identification filter of this embodiment at an incident angle of 0 degree and 30 degrees, wherein the vertical axis is transmittance (%). A shift of the passband center wavelength (defined as a center position of two wavelength points at 90% transmittance) in this embodiment is less than 10 nm at an incident angle of 30 degrees, which is equivalent to the 3D filter of FIG. 2 and FIG. 3. The difference is that although the number of layers on the bandpass film surface in this embodiment is reduced by more than a half, the transition band jitter of the filter is not reduced but is improved: the width of the transition band at wavelength points from 90% transmittance to 10% transmittance is 4.3 nm in the short-waveband direction and is 4.9 nm in the long-waveband direction.

FIG. 5 is a diagram of optical density of the 3D identification filter of this embodiment at 0 degree. To solve the problem of insufficient blocking of the bandpass film surface for the waveband of 600 to 800 nm, a multilayer blocking film is coated on the blocking film surface of the filter to increase the blocking of the bandpass film surface for this waveband. After the blocking film is added, the OD4 blocking range of the filter can cover the entire visible light waveband.

Table 1 is a list comparing the exemplary 3D identification filter of FIG. 2 with the 3D identification filter of FIG. 3 according to the present invention. It can be seen that the exemplary 3D identification filter and the 3D identification filter according to the embodiment of the present invention have the same passband range and angle drift, but that of the embodiment of the present invention has significant advantages: (a) the number of film layers on the bandpass film surface is significantly reduced by more than a half in this embodiment; (b) the jitter of the transition band is higher; and (c) the OD4 blocking band of the present invention can cover the entire visible light waveband.

TABLE 1

| Composition and | | | |
|---|---|---|---|
| Performance | | Embodiments of the | |
| Comparison | Example - Prior Art | Present Invention | |
| Design passband | 848 nm-861 nm | | |
| Center wavelength shift | <10 nm | | |
| as incident angle changes | | | |
| from 0 to 30 degrees | | | |
| High refractive index layer | Si:H (n = 3.65) | | |
| Medium refractive | None | M1 | (n = 1.91), |
| index layer | | M2 | (n = 2.71) |

| Low refractive index layer | SiO₂ (n = 1.48) | |
|---|---|---|
| Number of layers of | 41 | 19 |
| bandpass film system | | |
| Thickness of bandpass | 4.4 μm | 4.1 μm |
| film system | | |
| Jitter (90% T to 10% T) | 6.8 nm in short-wave | 4.3 nm in short-wave |
| | band direction, 6.9 nm | band direction, 4.9 nm |
| | in long-wave band | in long-wave band |
| | direction | direction |
| OD4 blocking band range | <380 nm to 684 nm | <380 nm to 827 nm |

In the process of production, the preparation of the bandpass film surface is much more difficult than that of the blocking film surface. The number of film layers on a simplified bandpass film surface reduces the preparation difficulty of the film system and improves production efficiency and yield; higher jitter means that the transition band of the filter from high transmittance to high blocking is narrower and the suppression of noise light near the transition band is better; and deeper visible light blocking helps to suppress visible light. Table 2 and Table 3 respectively illustrate the detailed design of the filter film layers on the two surfaces of this embodiment, including the layer number (from substrate to air), the material of the layers, the refractive index of the layers, and the physical thickness.

TABLE 2
Exemplary Film System Composition - Bandpass Film Surface

| Layer | | Refractive | | Physical |
|---|---|---|---|---|
| No. | Material | Index Type | n (860 nm) | Thickness (nm) |
| 1 | M1 | Medium | 1.91 | 123.9 |
| 2 | SiO₂ | Low | 1.48 | 171.2 |
| 3 | Si:H | High | 3.62 | 470.9 |
| 4 | SiO₂ | Low | 1.48 | 155.8 |
| 5 | M2 | Medium | 2.71 | 76.4 |
| 6 | SiO₂ | Low | 1.48 | 131.7 |
| 7 | Si:H | High | 3.62 | 477.4 |
| 8 | SiO₂ | Low | 1.48 | 142.6 |
| 9 | Si:H | High | 3.62 | 58.9 |
| 10 | SiO₂ | Low | 1.48 | 139.4 |
| 11 | Si:H | High | 3.62 | 476.8 |
| 12 | SiO₂ | Low | 1.48 | 137.8 |
| 13 | Si:H | High | 3.62 | 60.3 |
| 14 | SiO₂ | Low | 1.48 | 145.1 |
| 15 | Si:H | High | 3.62 | 472.8 |
| 16 | SiO₂ | Low | 1.48 | 154.3 |
| 17 | M2 | Medium | 2.71 | 79.8 |
| 18 | SiO₂ | Low | 1.48 | 155.5 |
| 19 | Si:H | High | 3.62 | 472.6 |

TABLE 3
Embodiment Film System Composition - Blocking Film Surface

| Layer | | | Physical |
|---|---|---|---|
| No. | Material | n (860 nm) | Thickness (nm) |
| 1 | Si:H | 3.62 | 18.6 |
| 2 | SiO₂ | 1.48 | 96.5 |
| 3 | Si:H | 3.62 | 39.3 |
| 4 | SiO₂ | 1.48 | 88.7 |
| 5 | Si:H | 3.62 | 40.0 |
| 6 | SiO₂ | 1.48 | 99.3 |
| 7 | Si:H | 3.62 | 40.7 |
| 8 | SiO₂ | 1.48 | 97.6 |
| 9 | Si:H | 3.62 | 39.9 |
| 10 | SiO₂ | 1.48 | 98.8 |
| 11 | Si:H | 3.62 | 40.3 |
| 12 | SiO₂ | 1.48 | 99.1 |
| 13 | Si:H | 3.62 | 40.0 |
| 14 | SiO₂ | 1.48 | 100.4 |
| 15 | Si:H | 3.62 | 41.1 |
| 16 | SiO₂ | 1.48 | 94.3 |
| 17 | Si:H | 3.62 | 39.7 |
| 18 | SiO₂ | 1.48 | 99.1 |
| 19 | Si:H | 3.62 | 41.4 |
| 20 | SiO₂ | 1.48 | 96.4 |
| 21 | Si:H | 3.62 | 39.4 |
| 22 | SiO₂ | 1.48 | 99.7 |
| 23 | Si:H | 3.62 | 40.3 |
| 24 | SiO₂ | 1.48 | 99.8 |
| 25 | Si:H | 3.62 | 39.4 |
| 26 | SiO₂ | 1.48 | 91.0 |
| 27 | Si:H | 3.62 | 39.8 |
| 28 | SiO₂ | 1.48 | 103.4 |
| 29 | Si:H | 3.62 | 41.3 |
| 30 | SiO₂ | 1.48 | 92.5 |
| 31 | Si:H | 3.62 | 18.9 |

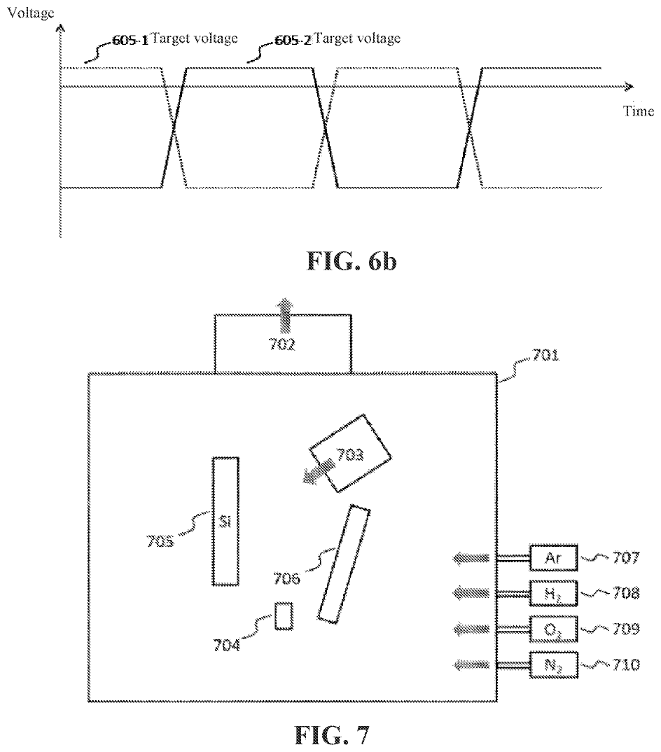

The high refractive index layer Si:H and the medium refractive index layer of the filter film layer of the filter of the present invention are realized by way of vacuum sputtering deposition. FIG. 6a schematically shows a vacuum sputtering system that can be used to prepare the 3D identification filter of the present invention, which is a mid-frequency magnetron sputtering system. 601 is the chamber of the sputtering system. 602 is a vacuum pumping system, which can specifically be one or several of a mechanical pump, a diffusion pump, a condensing pump, and a molecular pump, preferably a combination of a mechanical pump and a molecular pump. 603 is a mid-frequency power supply that includes two outputs to the sputtering target with an output power at a kW level and a frequency of 5 to 100 kHz, preferably with an output power of 8 to 10 kW and an operating frequency of 40 kHz. The sputtering unit consists of a pair of 604-1, 604-2 magnets and a pair of 605-1, 605-2 targets, and the 604 magnets are located on the back side of the 605 targets to constrain the electron trajectory. When the Si:H material is sputtered, the targets 605-1, 605-2 are silicon targets of the same size. During sputtering, the substrate 606 is located opposite to the target. Although FIG. 6a is a structure in which the substrate is located below the target, the actual selection may also be that the target is located below the substrate. Process gases that may be used in the device are argon 607, hydrogen 608, oxygen 609, and nitrogen 610. These process gases are introduced into the chamber near the sputtering unit through a pipeline. The pipeline is equipped with a flowmeter for adjusting and monitoring the gas flow. Argon 607 is the working gas, and hydrogen 608, oxygen 609, and nitrogen 610 are reaction gases. The vacuum pumping system 602 pumps away undesired gases, and the entire sputtering is performed in high vacuum. As a preferred case, the sputtering system may be provided with an assisting ion source 611, and argon, hydrogen, oxygen, and nitrogen may be partially or completely introduced into the chamber through the assisting ion source 611 to increase the ion activation and improve the film forming quality. As a preferred case, a uniformity correction plate 612 may be disposed between the target 605 and the substrate 606, and the uniformity distribution of the deposited material at different positions of the substrate 606 may be corrected by designing the shape of a shield on the correction plate.

FIG. 6b is a schematic timing diagram of the voltage at the target of the exemplary mid-frequency magnetron sputtering system, wherein the horizontal axis is time and the vertical axis is voltage. In the process of sputtering, the two targets 605-1, 605-2 are periodically alternately sputtered, which is advantageous for suppressing the arcing phenomenon and increasing the deposition rate as compared with the conventional DC sputtering.

FIG. 7 schematically shows a vacuum sputtering system which can be used to prepare the 3D identification filter of the present invention, which is an ion beam sputtering system. 701 is the chamber of the sputtering system. 702 is a vacuum pumping system, which can specifically be one or several of a mechanical pump, a diffusion pump, a condensing pump, and a molecular pump, preferably a combination of a mechanical pump and a condensing pump. 703 is an ion beam source, which can specifically be a Kaufman type ion source, a microwave type ion source, or a radio frequency type ion source, preferably a radio frequency type ion source. The ion beam source 703 uses gas discharge to generate plasma, which is accelerated by an electric field to form an ion beam. The ion beam bombards the target 705 directly after passing through the neutralizer 704. When the Si:H material is deposited, the target 705 is a silicon target. The sputtering material is deposited on the substrate 706. Process gases that may be used in the device are argon 707, hydrogen 708, oxygen 709, and nitrogen 710. These process gases are introduced into the chamber through a pipeline and are completely or partially introduced into the ion beam source 703. The pipeline is equipped with a flowmeter for adjusting and monitoring the gas flow. Argon 707 is the working gas, and hydrogen 708, oxygen 70), and nitrogen 710 are reaction gases. The vacuum pumping system 702 pumps away undesired gases, and the sputtering process is performed in high vacuum. Similarly, as a preferred case, the sputtering system may be provided with an assisting ion source and a uniformity correction plate, but these are not shown in the schematic diagram.

In addition to the high refractive index layer and the low refractive index layer, the 3D identification filter of the present invention innovatively uses at least one medium refractive index layer. The refractive index of the medium refractive index layer in the range of 800 to 1800 nm is greater than 1.6 and less than 3, and may have the property of a continuously adjustable refractive index during preparation. Using at least one medium refractive index layer whose refractive index is continuously adjustable, good phase matching between cavity layers in the bandpass film system can be achieved, so that the number of layers of the bandpass film system can be significantly reduced while maintaining high jitter of the filter. The method for preparing a material whose refractive index is continuously adjustable in the range of 1.6 to 3 is described in detail below.

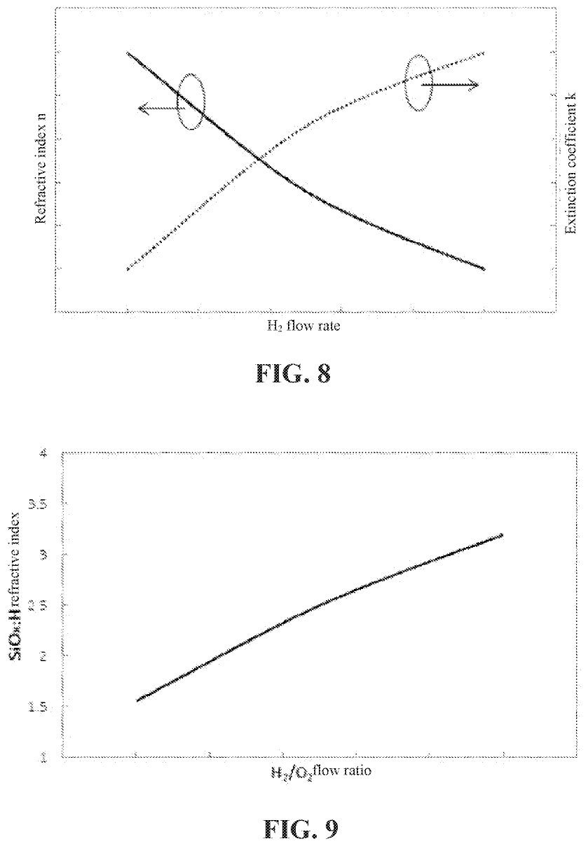

Method 1: Adjust the flow rate of hydrogen to adjust the optical properties of Si:H. FIG. 8 is a schematic diagram of the relationship between the flow rate of hydrogen and the refractive index n and the extinction coefficient k of the deposited Si:H film layer. Increasing the H₂ flow rate can reduce the refractive index n as well as the extinction coefficient k of the Si:H material, whereas reducing the H₂ flow rate can increase the refractive index n as well as the extinction coefficient k of the Si:H material. The method of regulating H₂ is simple, but there are two issues to be noted: (a) it is difficult to realize that the refractive index of the material is adjustable in the range of 1.6 to 3 by only adjusting the H₂ flow rate, and the empirical limit of the refractive index adjustment range is 2.7 to 3; and (b) there is a sensitive relationship between the refractive index and the extinction coefficient of a material, and the extinction coefficient characterizes the absorption of light by the material, and an excessive extinction coefficient may lead to a significant decrease in the passband transmittance of the filter.

The selection of the H₂ flow rate is affected by the vacuum pumping speed of the sputtering system, the sputtering power for the target, and the flow rate of the working gas. The basic principle for adjusting the refractive index of the material by adjusting parameters such as the sputtering power (sputtering yield) for the target and the working gas (Ar flow) is the same as that by adjusting the H₂ flow rate—adjusting the composition ratio of H in the Si:H material. Therefore, these methods should be considered as of the same type.

Method 2: Adjust the ratio of the flow rates of hydrogen and oxygen to adjust the refractive index of the deposited SiOₓ:H film layer. FIG. 9 is a schematic diagram of the relationship between the ratio of the flow rates of hydrogen and oxygen and the refractive index of the deposited SiOₓ:H film layer. When the flow ratio of hydrogen to oxygen is 0, that is, only oxygen is introduced, the deposited material is SiO₂ and the refractive index is less than 1.6; and when only hydrogen is introduced, the deposited material is Si:H having a refractive index greater than 3. By adjusting the ratio of hydrogen to oxygen, the stoichiometric ratio of element components of the SiOₓ:H film layer (i.e., the value of x) can be adjusted to obtain a SiOₓ:H film layer having a desired refractive index. The extinction coefficient of SiOₓ:H is insensitive to the flow ratio of hydrogen to oxygen.

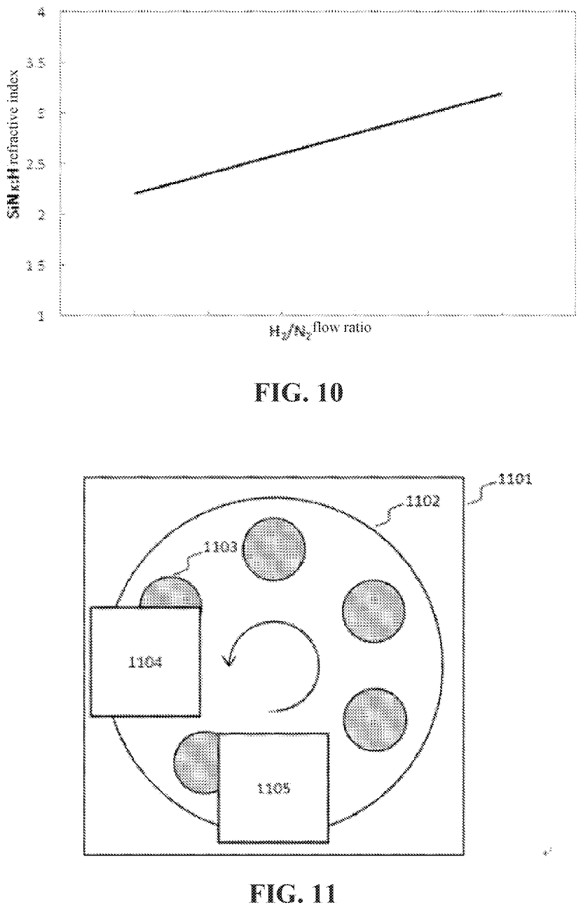

Method 3: Adjust the ratio of the flow rates of hydrogen and nitrogen to adjust the refractive index of the deposited SiNₓ:H film layer. FIG. 10 is a schematic diagram of the relationship between the ratio of the flow rates of hydrogen and nitrogen and the refractive index of the deposited SiNₓ:H film layer. Similarly, when the flow ratio of hydrogen to nitrogen is 0, that is, only nitrogen is introduced, the deposited material is silicon nitride, and the refractive index is about 2.0; and when only hydrogen is introduced, the deposited material is Si:H having a refractive index greater than 3. By adjusting the ratio of hydrogen to nitrogen, the stoichiometric ratio of element components of the SiNₓ:H film layer (i.e., the value of x) can be adjusted to obtain a SiN_{c}:H film layer having a desired refractive index. The extinction coefficient of SiNₓ:H is insensitive to the flow ratio of hydrogen to nitrogen.

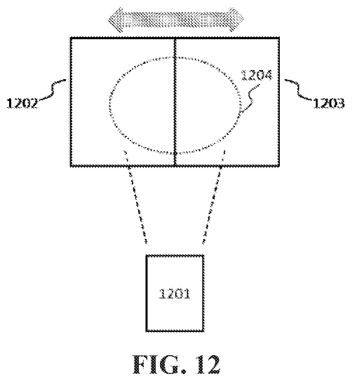

Method 4: Use a sputtered mixture of at least two materials, and obtain a mixture material with a continuously controllable refractive index by adjusting the proportion of the materials to be mixed. One method is to sputter materials of different refractive indexes in turn, and the thicknesses of different refractive index layers satisfy a specific theoretical relationship to achieve an effect similar to a “Quasi-rugate filter”. Another typical method is to co-sputter with a variety of materials. FIG. 11 is an apparatus that supports co-sputtering of two materials to make the refractive index of the deposited film layer continuously controllable, which can be additionally added to the mid-frequency magnetron sputtering system as described above. FIG. 11 is a top view of a sputtering system, wherein 1101 is the chamber of the sputtering system. Inside the chamber 1101 there is a turntable 1102 that can rotate at a high speed. A plurality of circular substrates 1103 are evenly placed on the turntable 1102 and rotate at a high speed with the turntable 1102. Two sputtering units 1104 and 1105 are fixed above the chamber and do not rotate with the turntable 1102. The material sputtered by the sputtering unit and the rotational speed of the turntable can be selected as required. For example, the sputtering unit 1104 sputters Nb₂O₅, the sputtering unit 1105 sputters SiO₂, and the rotational speed of the turntable is 120 rpm. When the system is in the co-sputtering state, the two sputtering units 1104 and 1105 operate simultaneously and sputter the corresponding material. When the substrate 1103 moves near to the sputtering unit 1104, a small amount of Nb₂O₅ material is deposited on the substrate, and when the substrate 1103 moves near to the sputtering unit 1105, a small amount of SiO₂ material is deposited on the substrate, and so on and so forth, so that a relatively uniform Nb₂O₅—SiO₂ mixture film layer is formed on the substrate, and the ratio is the ratio of the respective deposition rates of corresponding materials of the two sputtering units. Through process adjustment of the deposition rates of the two sputtering units, the composition ratio of the mixture film can be adjusted to control the refractive index of the mixture film layer.

FIG. 12 is another apparatus that supports co-sputtering of two materials to make the refractive index of the deposited film layer continuously controllable, which can be additionally added to the ion beam sputtering system as described above. 1201 is an ion beam source, which is equivalent to 703 in FIG. 6. The target consists of two parts, 1202 and 1203, which are spliced together. The two parts are two different materials. The 1204 region is the region where the ion beam bombards the target. Since the ion beam simultaneously bombards the two materials of the target, the material deposited by sputtering is a mixture of two materials corresponding to the target. For example, the 1202 part of the target may be a Si material, and the 1203 part of the target may be a SiO₂ material such that a mixture of the Si:H and SiO₂ materials can be obtained by co-sputtering. A fixing apparatus of the target has a displacement regulating function, and the composition ratio of different materials in the ion beam bombardment region 1204 can be changed by translation of the target in one direction, so that the refractive index of the deposited material is continuously controllable.

1. A 3D identification filter having a passband partially overlapping with a wavelength range of 800 nm to 1800 nm and a blocking band containing a wavelength range of 380 nm to 750 nm and comprising a substrate and filter film layers coated on both surfaces of the substrate, wherein
the filter film layer on one of the surfaces is composed of high refractive index layers, medium refractive index layers, and low refractive index layers that are stacked; the high refractive index layers are Si:H, and the refractive index of each high refractive index layer at 800 to 1800 nm is greater than 3; the refractive index of each medium refractive index layer at 800 to 1800 nm is greater than 1.6 and less than 3; the refractive index of each low refractive index layer at 800 nm to 1800 nm is less than 1.6; and the ratio of total physical thicknesses of all high refractive index layers and all low refractive index layers is greater than 1.5:1; and
the filter film layer on the other surface is composed of at least two layers of materials that are stacked, and the number of layers is not less than 15; the passband of the filter has a center wavelength that shifts less than 20 nm when the angle of incident light changes from 0 degree to degrees; a blocking level of the blocking band of the filter for the range of 380 nm to 750 nm is greater than OD4; and the edge of the passband of the filter is provided with a transition band, and the width of the transition band from 90% transmittance to 10% transmittance is less than 5 nm.

2. The 3D identification filter according to claim 1, wherein the material of the substrate is a silicon material, or a glass material based on silica, or plastic, or sapphire.

3. The 3D identification filter according to claim 1, wherein the passband has a center wavelength, and when the angle of incident light changes from 0 degree to 30 degrees, the shift of the center wavelength is less than 12 nm.

4. The 3D identification filter according to claim 1, wherein the medium refractive index layer is one of Si:H, TiO₂, Nb₂O₅, Ta₂O, SiO₂, and SiₓN_{y} or a mixture of at least two of them and when it is a mixture, the refractive index thereof has a property of being continuously adjustable in a range from 1.6 to 3 through process proportioning;
or the medium refractive index layer is SiOₓ:H, and the refractive index thereof has a property of being continuously adjustable in the range from 1.6 to 3 through process adjustment of stoichiometric ratio of element components;
or the medium refractive index layer is SiNₓ:H, and the refractive index thereof has a property of being continuously adjustable in the range from 1.6 to 3 through process adjustment of stoichiometric ratio of element components.

5. The 3D identification filter according to claim 1, wherein the low refractive index layer is SiO₂.

6. A method for manufacturing the filter according to claim 4, wherein the method is a mode of mid-frequency magnetron sputtering or ion beam sputtering to form a Si:H film layer by introducing hydrogen into a sputtering system.

7. The method according to claim 6, wherein the flow rate of hydrogen can be regulated to adjust the optical properties of the Si:H film layer.

8. The method according to claim 6, wherein the flow rates of hydrogen and oxygen can be simultaneously regulated to adjust the stoichiometric ratio of element components of a SiOₓ:H film layer, and then adjust the refractive index of SiOₓ:H.

9. The method according to claim 6, wherein the flow rates of nitrogen and hydrogen can be simultaneously regulated to adjust the stoichiometric ratio of element components of a SiNₓ:H film layer, and then adjust the refractive index of SiNₓ:H.

10. The method according to claim 6, wherein at least two layers of materials can be co-deposited, and the refractive index of the mixture film layer is adjusted by adjusting the ratio of the materials.
